(19) United States
(12) Patent Application Publication
(10) Pub. No.: US 2024/0105272 A1
(43) Pub. Date: Mar. 28, 2024

(54) SEMICONDUCTOR MEMORY DEVICE

(71) Applicant: Kioxia Corporation, Tokyo (JP)

(72) Inventor: Eietsu TAKAHASHI, Yokohama Kanagawa (JP)

(21) Appl. No.: 18/460,262

(22) Filed: Sep. 1, 2023

(30) Foreign Application Priority Data
Sep. 22, 2022 (JP) 2022-151568

(51) Int. Cl. G11C 16/34; G11C 16/04; G11C 16/08; G11C 16/26

(52) U.S. Cl. CPC G11C 16/3459; G11C 16/0483; G11C 16/08; G11C 16/26

(57) ABSTRACT

A semiconductor memory device includes: a first bit line connected to a first string including memory cell transistors; a second bit line connected to a second string including memory cell transistors; a source line connected to the first string and the second string; a word line connected to gates of the memory cell transistors in same rows of the first and strings; a voltage generation circuit configured to apply a first voltage to the first bit line according to a first target level, apply a second voltage to the second bit line according to a second target level, and apply a third voltage to the source line; and a row decoder configured to apply a fourth voltage to the word line to which a first memory cell transistor of the first string and a second memory cell transistor of the second string are connected during a verification operation.

### CROSS-REFERENCE TO RELATED APPLICATION

This application is based upon and claims the benefit of priority from Japanese Patent Application No. 2022-151568, filed Sep. 22, 2022, the entire contents of which are incorporated herein by reference.

### FIELD

Embodiments described herein relate generally to a semiconductor memory device.

### BACKGROUND

A semiconductor memory device includes a NAND-type memory. In the semiconductor memory device, as the number of values increases, the number of times of verification increases to deteriorate the performance.

### DESCRIPTION OF THE DRAWINGS

FIG. 1 is a block diagram illustrating an example of a configuration of a memory system.

FIG. 2 is a block diagram illustrating an example of a nonvolatile memory in FIG. 1.

FIG. 3 is a diagram illustrating an example of a configuration of a block of a memory cell array having a three-dimensional structure.

FIG. 4 is a block diagram illustrating an example of a sense amplifier unit group and a data register in FIG. 2.

FIG. 5 is a circuit diagram illustrating an example of a specific configuration of a sense amplifier unit SAU in FIG. 4.

FIG. 6A is an explanatory diagram illustrating an example of a verification operation according to a first embodiment.

FIG. 6B is an explanatory diagram illustrating an example of the verification operation according to the first embodiment.

FIG. 6C is an explanatory diagram illustrating an example of the verification operation according to the first embodiment.

FIG. 7 is an explanatory diagram illustrating an example of a change in a voltage applied to a selected word line WLsel in a program operation and a verification operation.

FIG. 8 is an explanatory diagram illustrating another example of the change in the voltage applied to the selected word line WLsel in the program operation and the verification operation.

FIG. 9 is a block diagram illustrating an example of a nonvolatile memory according to a second embodiment.

FIG. 10A is an explanatory diagram illustrating an example of a verification operation of the second embodiment.

FIG. 10B is an explanatory diagram illustrating an example of the verification operation of the second embodiment.

FIG. 10C is an explanatory diagram illustrating an example of the verification operation of the second embodiment.

### DETAILED DESCRIPTION

Embodiments provide a semiconductor memory device that can improve performance by reducing the number of times of verification.

In general, according to one embodiment, a semiconductor memory device includes: a first bit line connected to one end of a first string including a first select transistor, a plurality of memory cell transistors, and a second select transistor; a second bit line connected to one end of a second string including a third select transistor, a plurality of memory cell transistors, and a fourth select transistor; a source line commonly connected to the other end of the first string and the other end of the second string; a word line commonly connected to respective gates of the memory cell transistors in one or more same rows of the first string and the second string; a voltage generation circuit configured to apply a first voltage to the first bit line according to a first target level during a verification operation, apply a second voltage to the second bit line according to a second target level, and apply a third voltage to the source line; and a row decoder configured to apply a fourth voltage to the word line to which a first one of the memory cell transistors of the first string and a second one of the memory cell transistors of the second string to be verified are connected during the verification operation.

Hereinafter, embodiments of the present disclosure are described in detail with reference to the drawings.

### First Embodiment

(Configuration of Memory System)

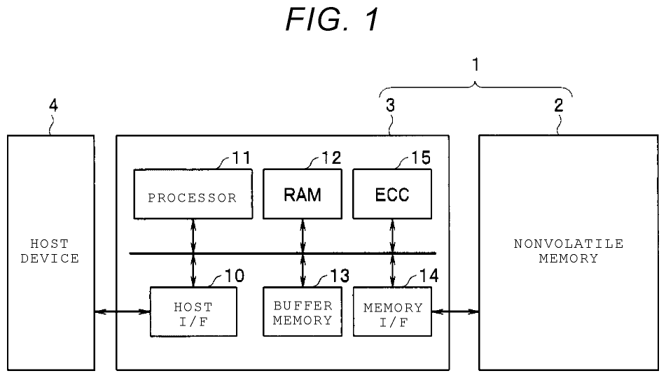

FIG. 1 is a block diagram illustrating an example of a configuration of a memory system. A memory system 1 according to the present embodiment includes a memory controller 3 and a nonvolatile memory 2. In addition, the nonvolatile memory 2 may include a plurality of memory chips. The memory system 1 can be connected to a host device 4. The host device 4 is, for example, an electronic device such as a personal computer or a mobile terminal.

The memory system 1 may be configured with implementing a plurality of chips that configure the memory system 1 on a motherboard on which the host device 4 is mounted and may be configured as a system large-scale integrated circuit (LSI) or a System-on-a-Chip (SoC) achieving the memory system 1 with one module. Examples of the memory system 1 include a memory card such as an SD card, a solid-state-drive (SSD), and an embedded-multi-media-card (eMMC).

The nonvolatile memory 2 is a NAND-type memory including a plurality of memory cells and stores data in a nonvolatile manner. A specific configuration of the nonvolatile memory 2 is described below.

For example, in response to the instruction from the host device 4, the memory controller 3 instructs the nonvolatile memory 2 to perform writing (also referred to as programming), reading, erasing, and the like. In addition, the memory controller 3 manages a memory space of the nonvolatile memory 2. The memory controller 3 includes a host interface (host I/F) circuit 10, a processor 11, a random access memory (RAM) 12, a buffer memory 13, a memory interface circuit (memory I/F) circuit 14, an error checking and correcting (ECC) circuit 15, and the like.

The host I/F circuit 10 is connected to the host device 4 via a host bus and performs an interface process with the host device 4. In addition, the host I/F circuit 10 transmits and receives an instruction, an address, and data to and from the host device 4.

The processor 11 is configured, for example, with a central processing unit (CPU). The processor 11 controls an operation of the entire memory controller 3. For example, when receiving a write instruction from the host device 4, the processor 11 issues a write instruction to the nonvolatile memory 2 in accordance with a write instruction from the host device 4 via the memory I/F circuit 14. The same is applied to reading and erasing. In addition, the processor 11 performs various processes for managing the nonvolatile memory 2 such as wear leveling.

The RAM 12 is used as a work area for the processor 11 and stores firmware data loaded from the nonvolatile memory 2 and various tables generated by the processor 11, and the like. The RAM 12 is configured, for example, with DRAM or SRAM.

The buffer memory 13 temporarily stores data transmitted from the host device 4 and temporarily stores data transmitted from the nonvolatile memory 2.

The memory I/F circuit 14 is connected to the nonvolatile memory 2 via a bus and performs an interface process with the nonvolatile memory 2. In addition, the memory I/F circuit 14 transmits and receives an instruction, an address, and data to and from the nonvolatile memory 2.

The ECC circuit 15 generates an error correction code for write data at the time of writing data, adds the error correction code to the write data, and transmits the error correction code and the write data to the memory I/F circuit 14. In addition, at the time of reading data, the ECC circuit 15 performs error detection and/or error correction on the read data by using the error correction code provided in the read data. In addition, the ECC circuit 15 may be provided in the memory I/F circuit 14.

(Configuration of Nonvolatile Memory)

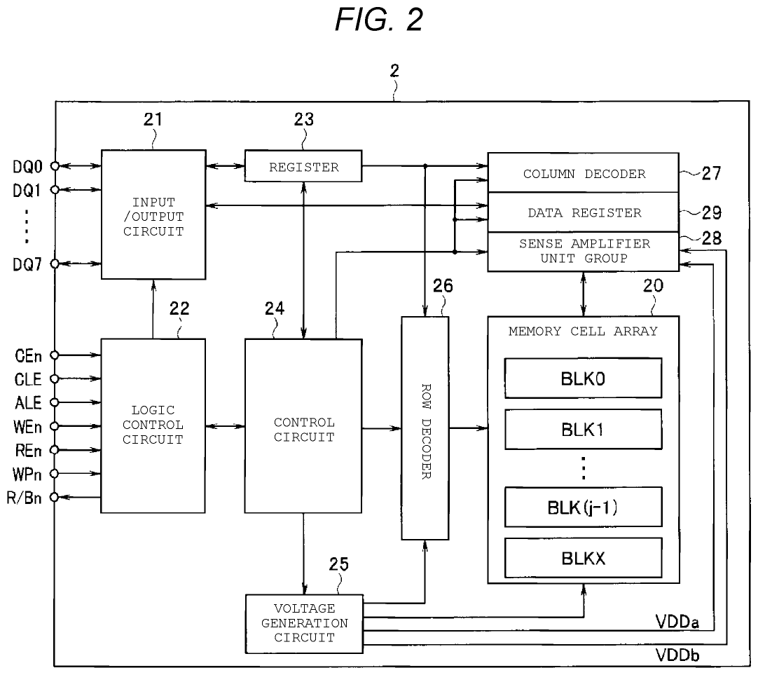

FIG. 2 is a block diagram illustrating an example of the nonvolatile memory 2 in FIG. 1. The nonvolatile memory 2 includes a memory cell array 20, an input/output circuit 21, a logic control circuit 22, a register 23, a control circuit 24, a voltage generation circuit 25, a row decoder 26, a column decoder 27, a sense amplifier unit group 28, and a data register (data cache) 29.

The memory cell array 20 includes j blocks BLK0 to BLK (j−1) and a block BLKX. j is an integer of 1 or more. Each of the plurality of blocks BLK includes a plurality of memory cell transistors. The memory cell transistor configures an electrically rewritable memory cell. In order to control a voltage applied to the memory cell transistor, a plurality of bit lines BL, a plurality of word lines WL, a source line CELSRC, and the like are located in the memory cell array 20. A specific configuration of the block BLK is described below.

The input/output circuit 21 and the logic control circuit 22 are connected to the memory controller 3 via a bus. The input/output circuit 21 transmits and receives signals DQ (for example, DQ0 to DQ7) to and from the memory controller 3 via a bus.

The logic control circuit 22 receives external control signals (for example, a chip enable signal CEn, a command latch enable signal CLE, an address latch enable signal ALE, a write enable signal WEn, a read enable signal REn, and a write protect signal WPn) from the memory controller 3 via a bus. “n” appended to a signal name indicates active low. In addition, the logic control circuit 22 transmits a ready/busy signal R/Bn to the memory controller 3 via a bus.

In a system configuration in which the plurality of nonvolatile memories 2 are used, the signal CEn is a signal for selecting and enabling the specific nonvolatile memory 2. The signal CLE enables latching of a command transmitted as the signal DQ to the register 23. The signal ALE enables latching of the address transmitted as the signal DQ to the register 23. The signal WEn enables writing. The signal REn enables reading. The signal WPn prohibits writing and erasing. During using a basic operation command, the signal R/Bn indicates whether the nonvolatile memory 2 is in a ready state in which writing, reading, and erasing operations are not performed (a state in which an instruction from the outside can be received) or a busy state (a state in which an instruction from the outside cannot be received).

The register 23 includes a command register, an address register, a status register, and the like. The command register temporarily stores a command. The address register temporarily stores an address. The status register temporarily stores data required for an operation of the nonvolatile memory 2. The register 23 is configured, for example, with an SRAM.

The control circuit 24 receives a command from the register 23 and comprehensively controls the nonvolatile memory 2 according to the sequence based on the command.

The voltage generation circuit 25 receives a power supply voltage from the outside of the nonvolatile memory 2 and generates a plurality of voltages required for a write operation, a read operation, and an erasing operation by using this power supply voltage. The voltage generation circuit 25 supplies the plurality of generated voltages to the memory cell array 20, the row decoder 26, the sense amplifier unit group 28, and the like. For example, the voltage generation circuit 25 supplies the voltages VDDa and VDDb to the sense amplifier unit group 28.

The row decoder 26 receives a low address from the register 23 and decodes this low address. The row decoder 26 performs a selection operation of a word line based on the decoded low address. In addition, a word line to which a memory cell transistor MT to be a writing and reading target is connected is referred to as a selected word line. Also, the row decoder 26 transmits a plurality of voltages required for a write operation, a read operation, and an erasing operation to the selected block BLK.

The column decoder 27 receives a column address from the register 23 and decodes this column address. The column decoder 27 supplies a predetermined voltage to each bit line BL based on the decoded column address.

During reading the data, the sense amplifier unit group 28 senses and amplifies the data read from the memory cell transistor to the bit line. In addition, during writing the data, the sense amplifier unit group 28 supplies write data to the bit lines BL.

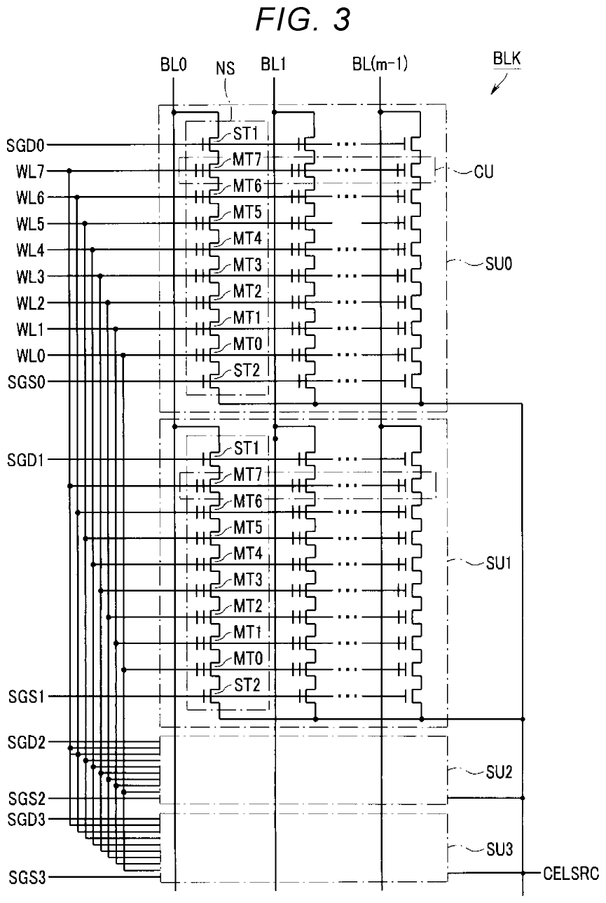

During reading the data, the data register 29 temporarily stores the data transmitted from the sense amplifier unit group 28 and serially transmits this data to the input/output circuit 21. In addition, during writing the data, the data register 29 temporarily stores data serially transmitted from the input/output circuit 21 and transmits this data to the sense amplifier unit group 28. The data register 29 is configured with an SRAM and the like. [0029] (Block Configuration of Memory Cell Array) FIG. 3 is a diagram illustrating an example of a configuration of the block of the memory cell array 20 having a three-dimensional structure. FIG. 3 illustrates one block BLK among the plurality of blocks that configure the memory cell array 20. Other blocks of the memory cell array also have the same configuration as in FIG. 3.

As illustrated, the block BLK includes, for example, four string units SU0 to SU3 (hereinafter, representatively referred to as string units SU). In addition, each string unit SU includes a NAND string NS including the plurality of memory cell transistors MT (MT0 to MT7) and select gate transistors ST1 and ST2. In addition, the number of the memory cell transistors MT provided in the NAND string NS is 8 in FIG. 3 but may be plural. The select gate transistors ST1 and ST2 are illustrated as one transistor in an electrical circuit but may be structurally the same as the memory cell transistor. In addition, as the select gate transistors ST1 and ST2, a plurality of select gate transistors may be used, respectively. Further, dummy cell transistors may be provided between the memory cell transistors MT and the select gate transistors ST1 and ST2.

The memory cell transistors MT are connected in series between the select gate transistors ST1 and ST2. The memory cell transistor MT7 on one end side (bit line side) is connected to the select gate transistor ST1, and the memory cell transistor MT0 on the other end side (source line side) is connected to the select gate transistor ST2.

Gates of the select gate transistors ST1 of the string units SU0 to SU3 are connected to select gate lines SGD0 to SGD3 (hereinafter, representatively referred to as the select gate lines SGD), respectively. In addition, gates of the select gate transistors ST2 of the string units SU0 to SU3 are connected to select gate lines SGS0 to SGS3 (hereinafter, representatively referred to as the select gate lines SGS), respectively. In addition, the gates of the plurality of select gate transistors ST2 in each of the blocks BLK may be connected to the common select gate line SGS.

The gates of the memory cell transistors MT0 to MT7 in the same block BLK are commonly connected to the word lines WL0 to WL7, respectively. That is, while the word lines WL0 to WL7 are commonly connected between the plurality of string units SU0 to SU3 in the same block BLK, the select gate lines SGD are independent from each other for each of the string units SU0 to SU3 in the same block BLK. The gates of the memory cell transistors MTi in the same rows in the block BLK are connected to the same word lines WLi.

The NAND strings NS each are connected to the corresponding bit lines. Accordingly, the memory cell transistors MT each are connected to the bit lines via the select gate transistors ST1 and ST2 or the other memory cell transistors MT provided in the NAND string NS. Generally, data of the memory cell transistors MT in the same block BLK is collectively erased. Meanwhile, typically, the reading and writing of the data are collectively performed for the plurality of memory cell transistors MT commonly connected to one word line WL located in one string unit SU. Such a set of the memory cell transistors MT sharing the word line WL in one string unit SU is referred to as a cell unit CU.

The write operation onto the cell unit CU is performed in page units. For example, when each cell is a triple level cell (TLC) that can store data of three bits (eight levels), one cell unit CU can store data of three pages. Three bits that each the memory cell transistor MT can store correspond to the three pages, respectively.

(Configuration of Sense Amplifier Unit and Data Register)

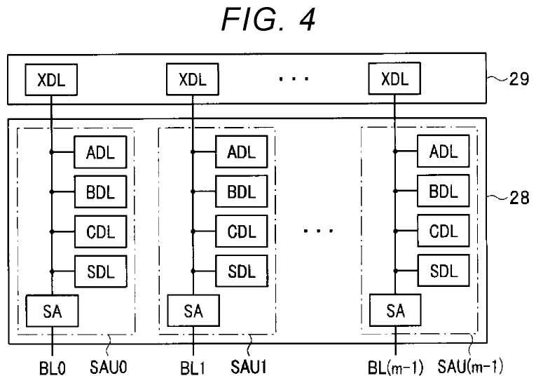

FIG. 4 is a block diagram illustrating an example of the sense amplifier unit group 28 and the data register 29 in FIG. 2.

The sense amplifier unit group 28 includes the sense amplifier units SAU0 to SAU (m−1) (hereinafter, representatively referred to as the sense amplifier units SAU) corresponding to the bit lines BL0 to BL(m−1). The sense amplifier units SAU each include a sense amplifier SA and data latch circuits SDL, ADL, BDL, and CDL. The sense amplifier SA and the data latch circuits SDL, ADL, BDL, and CDL are connected so that data can be transmitted to each other.

The data latch circuits SDL, ADL, BDL, and CDL temporarily store data. During the write operation, the sense amplifier SA controls the voltages of the bit lines BL according to the data that the data latch circuit SDL stores. The data latch circuits ADL, BDL, and CDL are used for a multi-value operation in which the memory cell transistor MT stores data of two or more bits. That is, the data latch circuit ADL is used for storing write data of a lower page. The data latch circuit BDL is used for storing write data of a middle page. The data latch circuit CDL is used for storing write data of an upper page. The number of data latch circuits provided in the sense amplifier unit SAU is determined according to the number of bits that one memory cell transistor MT stores.

During the read operation, the sense amplifier SA senses data read to the corresponding bit line BL and determines whether the data is data of “0” or data of “1”. In addition, during the write operation, the sense amplifier SA applies the voltage to the bit line BL based on the write data.

The data register 29 include the data latch circuits XDL in the number corresponding to the sense amplifier units SAU0 to SAU(m−1). The data latch circuits XDL are connected to the input/output circuit 21. The data latch circuits XDL temporarily store write data transmitted from the input/output circuit 21 and temporarily store read data transmitted from the sense amplifier unit SAU. More specifically, data transmission between the input/output circuit 21 and the sense amplifier unit group 28 is performed via the data latch circuits XDL for one page. The write data that the input/output circuit 21 receives is transmitted to any one of the data latch circuits ADL, BDL, and CDL via the data latch circuits XDL. The read data read by the sense amplifier SA is transmitted to the input/output circuit 21 via the data latch circuits XDL.

(Specific Configuration of Sense Amplifier Unit)

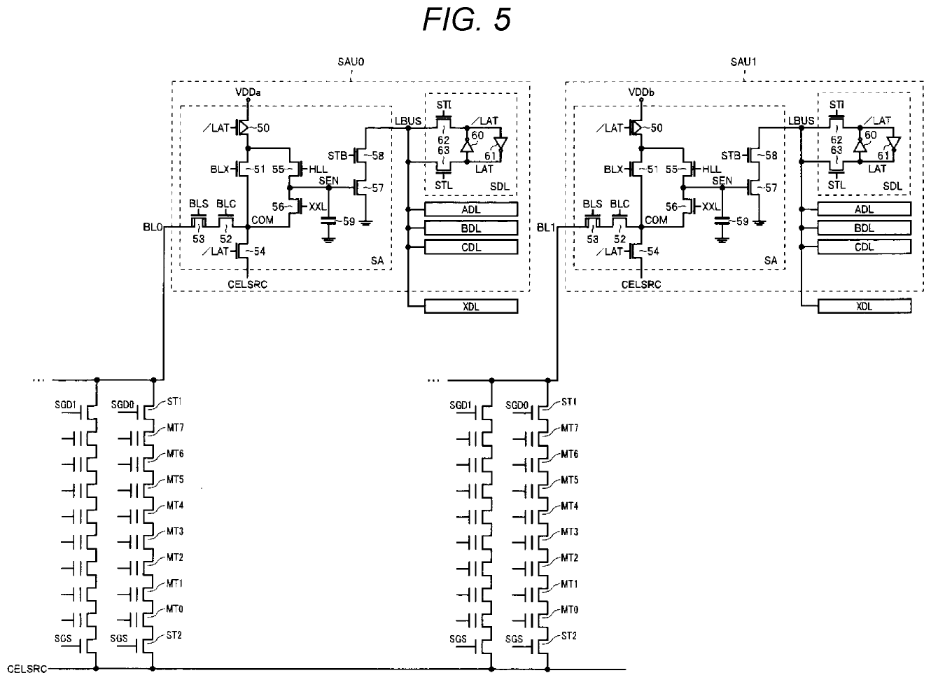

FIG. 5 is a circuit diagram illustrating an example of a specific configuration of the sense amplifier unit SAU in FIG. 4. FIG. 5 illustrates a configuration of the sense amplifier units SAU0 and SAU1 among the sense amplifier units SAU in FIG. 4 and a configuration of a part of the NAND strings NS connected to the sense amplifier units SAU0 and SAU1. The configurations of the sense amplifier units SAU0 and SAU1 are the same. However, as illustrated in FIG. 5, the voltage VDDa is supplied to the sense amplifier unit SAU0, and the voltage VDDb is supplied to the sense amplifier unit SAU1. That is, individual voltages are applied to the sense amplifier units SAU0 and SAU1 by the voltage generation circuit 25.

As illustrated in FIG. 5, the sense amplifier units SAU0 and SAU1 include a sense amplifier section SA and the data latch circuits SDL, ADL, BDL, and CDL. The sense amplifier section SA and the data latch circuits SDL, ADL, BDL, CDL, and XDL are connected to each other via a bus LBUS so that data can be received from each other.

The data latch circuit SDL includes, for example, inverters 60 and 61 and n channel MOS transistors 62 and 63. The input node of the inverter 60 and the output node of the inverter 61 are connected to a node LAT. The input node of the inverter 61 and the output node of the inverter 60 are connected to a node/LAT. The data of the nodes/LAT and LAT is stored in the inverters 60 and 61. The write data is supplied to the node LAT. The data stored in the node/LAT is inverse data of the data stored in the node LAT.

One end of the drain-source path of the transistor 62 is connected to the node/LAT, and the other end is connected to the bus LBUS. In addition, one end of the drain-source path of the transistor 63 is connected to the node LAT, and the other end is connected to the bus LBUS. A control signal STL is input to the gate of the transistor 63, and a control signal STI is input to the gate of the transistor 62.

In addition, the circuit configurations of the data latch circuits ADL, BDL, CDL, and XDL are the same as the data latch circuit SDL, and the description thereof is omitted. In addition, various control signals supplied to the sense amplifier unit SAU is given from the control circuit 24.

The sense amplifier section SA includes, for example, a p channel MOS transistor 50, n channel MOS transistors 51 to 58, and a capacitor 59.

In the read operation, the sense amplifier section SA senses the data read to the corresponding bit line BL and determines whether the read data is “0” or “1”. In addition, in the program operation, the sense amplifier section SA sets the corresponding bit line BL to the voltage value in accordance with the write data of “0” and “1”.

In the sense amplifier section SA, the transistors 50 to 54 are involved in the program operation. A source-drain path of the transistor 50 as the second transistor and a drain-source path of the transistor 51 are connected in series between the power supply lines that supply the voltages VDDa and VDDb that are internal power supply voltages and a node COM. In addition, a drain-source path of the transistor 54 as the third transistor is connected between the node COM and a node CELSRC that supplies the voltage VSS that is a ground voltage. In addition, a drain-source path of the transistor 52 as the first transistor and a drain-source path of the transistor 53 are connected in series between the node COM and the bit line BL.

The gates of the transistors 50 and 54 are connected to the node/LAT. Therefore, when the node LAT corresponding to data of “0” is in a low level (hereinafter, referred to as Level L), the node/LAT is maintained in a high level (hereinafter, referred to as Level H), the transistor 50 is turned off, and the transistor 54 is turned on. In contrary, when the node LAT corresponding to data of “1” is in Level H, the node/LAT is maintained in Level L, the transistor 50 is turned on, and the transistor 54 is turned off.

During the program operation, control signals HLL and XXL supplied to the gates of the transistors 55 and 56 each are in Level L, and the transistors 55 and 56 are turned off. A control signal BLX supplied to the transistor 51 is in Level H, and the transistor 51 is turned on. In addition, during a normal program operation, the transistors 52 and 53 are electrically connected by control signals BLC and BLS.

Therefore, when data of “0” is stored in the node LAT, the transistor 50 is turned off, the transistor 54 is turned on, a bit line voltage of the voltage VSS (for example, 0 V) or the like from the node CELSRC is supplied to the bit line BL. In addition, if data of “1” is stored in the node LAT, the transistor 50 is turned on, the transistor 54 is turned off, and, for example, a bit line voltage such as 2.5 V is supplied to the bit lines BL according to the control signals BLC and BLS applied to the transistors 52 and 53.

(Verification Operation)

The verification operation is an operation of reading data of the memory cell transistor MT and determining whether the threshold voltage of the memory cell transistor MT reaches a desired level, after the program operation. During this verification operation, all the transistors 50 to 58 and the capacitor 59 of the sense amplifier section SA are involved. A drain-source path of the transistor 55 and a drain-source path of the transistor 56 are connected in series between the drain of the transistor 50 and the node COM. In addition, a drain-source path of the transistor 58 and a drain-source path of the transistor 57 are connected in series between the bus LBUS and a reference potential point. A source of the transistor 55 and a drain of the transistor 56 are connected to a sense node SEN, and the sense node SEN is connected to the gate of the transistor 57. The control signal HLL or XXL, a voltage of the sense node SEN, or a control signal STB is applied to each gate of the transistors 55 to 58.

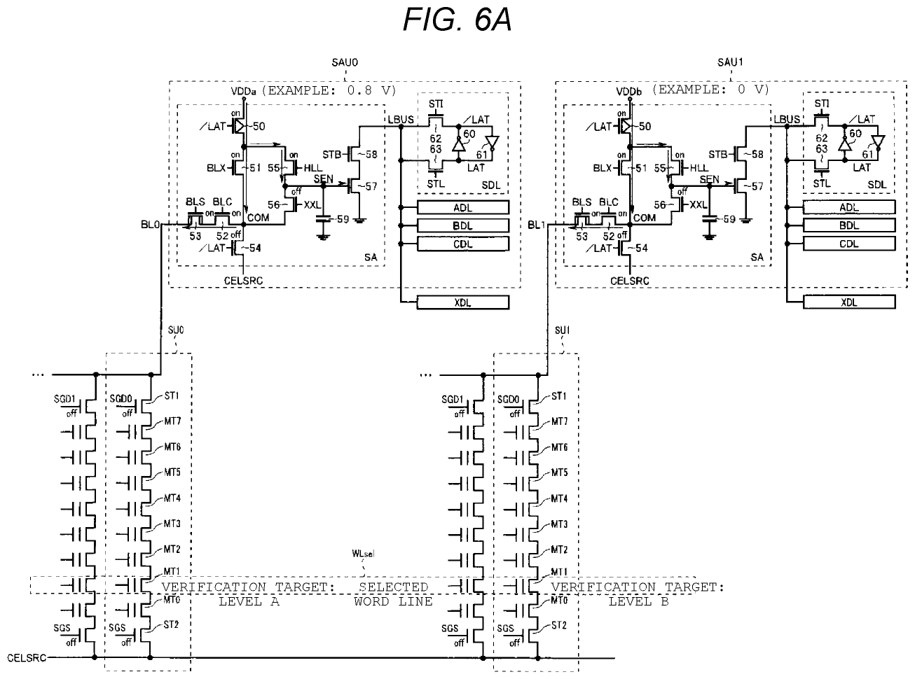

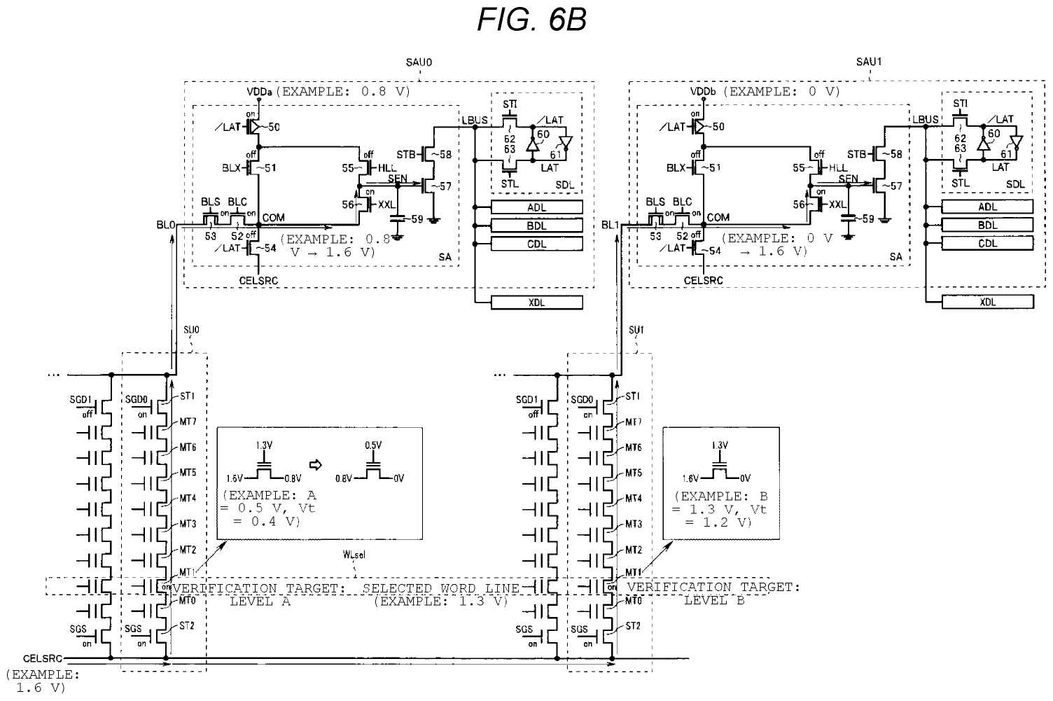

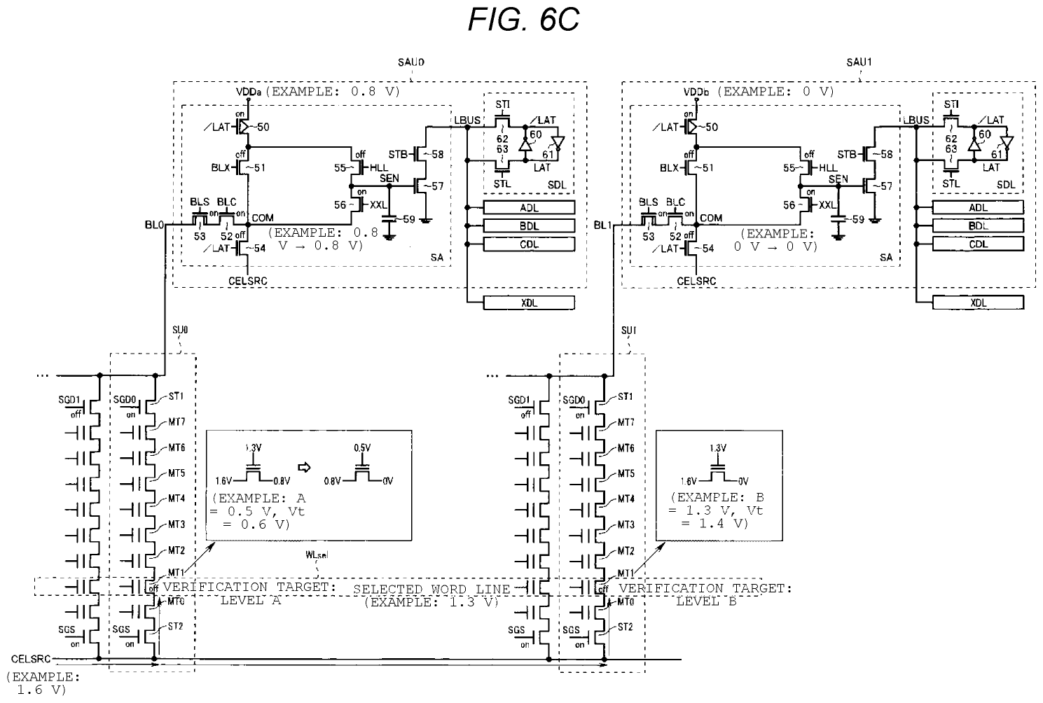

Here, the verification operation is specifically described with reference to FIGS. 6A, 6B, and 6C. FIG. 6A to 6C are explanatory diagrams illustrating an example of the verification operation according to the first embodiment.

In the above description, the memory cell transistors MT1 of the selected string units SU0 and SU1 are the memory cell transistors MT to be verified. In the memory cell transistor MT1 of the selected string unit SU0, a target level of the verification operation is Level A. Meanwhile, in the memory cell transistor MT1 of the selected string unit SU1, the target level of the verification operation is Level B.

The control circuit 24 turns on the transistors 50, 51, 52, 53, and 55 of the sense amplifier units SAU0 and SAU1 and turns of the transistor 56.

The voltage generation circuit 25 applies the voltage VDDa (for example, 0.8 V) to the bit line BL0 connected to the memory cell transistor MT1 of which the target level of the verification operation is Level A.

Meanwhile, the voltage generation circuit 25 applies the voltage VDDb (for example, 0 V) to the bit line BL1 connected to the memory cell transistor MT1 of which the target level of the verification operation is Level B.

Therefore, the sense node SEN of the selected string unit SU0 is charged to 0.8 V, and the sense node SEN of the selected string unit SU1 is charged to 0 V.

Next, as illustrated in FIG. 6B, the control circuit 24 turns off the transistors 51 and 55 and turns on the transistor 56, in the state of FIG. 6A.

The row decoder 26 applies a predetermined voltage (for example, 2.5 V) to the select gate line SGD0 and the select gate line SGS and turns on the select gate transistors ST1 and ST2 of the selected string units SU0 and SU1.

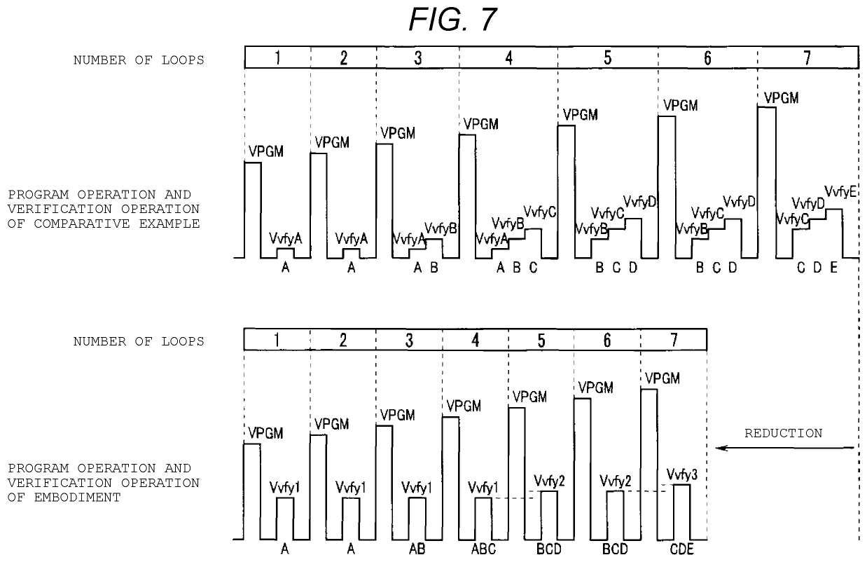

Also, the row decoder 26 applies a verification voltage Vvfy1 (for example, 1.3 V) to a selected word line WLsel and applies a voltage VREAD (for example, 5 V) higher than the verification voltage Vvfy1 to an unselected word line. The verification voltage Vvfy1 is changed according to the target level of the verification operation. The row decoder 26 increases the voltage to verification voltages Vvfy2, Vvfy3, and the like higher than the verification voltage Vvfy1 as the target level of the verification operation increases (see FIG. 7).

The voltage generation circuit 25 applies a predetermined voltage (for example, 1.6 V) to the source line CELSRC.

The memory cell transistor MT1 of the selected string unit SU0 applies a voltage of 1.3 V to a gate terminal, a voltage of 1.6 V to a source terminal, and a voltage of 0.8 V to a drain terminal. This is equivalent to a case where a voltage of 0.5 V is applied to the gate terminal, a voltage of 0.8 V is applied to the source terminal, and a voltage of 0 V is applied to the drain terminal.

Therefore, the memory cell transistor MT1 of the selected string unit SU0 is turned on, since a case where a threshold voltage Vt is 0.4 V is equivalent to a case where the verification voltage Vvfy1 of 0.5 V is input to the gate terminal. Therefore, the current flows from the source line CELSRC to the sense node SEN via the transistors 53, 52, and 56, and the voltage of the sense node SEN increases from 0.8 V to 1.6 V.

In addition, the memory cell transistor MT1 of the selected string unit SU1 is turned on, since the verification voltage Vvfy1 of 1.3 V is input to the gate terminal while the threshold voltage Vt is 1.2 V. Therefore, the current flows from the source line CELSRC to the sense node SEN via the transistors 53, 52, and 56, and the voltage of the sense node SEN increases from 0 V to 1.6 V.

When the sense node SEN is charged, the control circuit 24 determines that the verification is failed. For the memory cell transistor MT determined that the verification is failed, the control circuit 24 increases a voltage VPGM applied to the selected word line WLsel to be higher than that in a case where the previous program operation since the writing is not completed and performs a program operation.

FIG. 6C illustrates an example in which the threshold voltage Vt of the memory cell transistor MT1 of the selected string unit SU0 is increased to 0.6 V, and the threshold voltage Vt of the memory cell transistor MT1 of the selected string unit SU1 is increased to 1.4 V by the program operation. The operation state in the verification operation after the program operation (on/off of a transistor or applied voltage) is the same as the state of FIG. 6B.

The memory cell transistor MT1 of the selected string unit SU0 is turned off since a case where the threshold voltage Vt is 0.6 V is equivalent to a case where the verification voltage Vvfy1 of 0.5 V is input to the gate terminal. Therefore, the sense node SEN of the sense amplifier unit SAU0 is not charged and is 0.8 V without change.

In addition, the memory cell transistor MT1 of the selected string unit SU1 is turned off, since the verification voltage Vvfy1 of 1.3 V is input to the gate terminal while the threshold voltage Vt is 1.4 V. Accordingly, the sense node SEN of the sense amplifier unit SAU1 is not charged and is 0 V without change.

When the sense node SEN is not charged, the control circuit 24 determines that the verification is passed. The control circuit 24 determines that the write operation is completed for the memory cell transistor MT determined that the verification is passed, and does not perform the following program operations and verification operations.

FIG. 7 is an explanatory diagram illustrating an example of a change in a voltage applied to the selected word line WLsel in the program operation and the verification operation.

In the write operation, data is written by repeating a combination of the program operation and the verification operation a plurality of times. This repetition operation is referred to as a “loop”. The program voltage VPGM is set to the lowest voltage value in the first loop and becomes a higher voltage value as the loop progresses.

For example, in the program operation and the verification operation of the comparative example, in the third loop, the verification is performed on the memory cell transistors MT in which the target levels of the verification operation are Level A and Level B.

After the application of the program voltage VPGM, in a state in which a verification voltage VvfyA is applied to the selected word line WLsel for performing the verification to Level A, it is determined whether the memory cell transistor MT of Level A is in a write insufficient cell state or in a write complete cell state.

Next, in a state in which a verification voltage VvfyB for performing the verification for Level B is applied to the selected word line WLsel, it is determined whether the memory cell transistor MT of Level B is in the write insufficient cell state or in the write complete cell state.

In addition, in the fourth loop, in subsequent to the verification of Level A and Level B, the verification for Level C is performed. In the verification for Level C, in a state in which a verification voltage VvfyC is applied to the selected word line WLsel, it is determined whether the memory cell transistor MT of Level C is in the write insufficient cell state or in the write complete cell state.

In this manner, in the program operation and the verification operation in the comparative example, the verification operation is performed a plurality of times according to a plurality of states.

In contrast, according to the present embodiment, the voltages applied to the bit lines BL0 and BL1 are changed according to the target level of the verification operation, and the voltage from the source line CELSRC side is applied to charge the sense node SEN. By applying the different voltages VDDa and VDDb to the bit lines BL0 and BL1 according to the target levels of the verification operation, a back gate bias is changed, and a plurality of threshold values are read with one verification voltage Vvfy1.

For example, in the third loop, after the application of the program voltage VPGM, in a state in which the verification voltage Vvfy1 for performing the verification for Level A and Level B is applied to the selected word line WLsel, it is determined whether the memory cell transistors MT of Level A and Level B each are in the write insufficient cell state or in the write complete cell state.

In this manner, according to the present embodiment, since the verification operation for a plurality of states can be performed once, the number of times of verification can be reduced compared with that in the comparative example. As a result, according to the present embodiment, the period of time for the write operation can be reduced compared with that in the comparative example, and thus the performance can be improved.

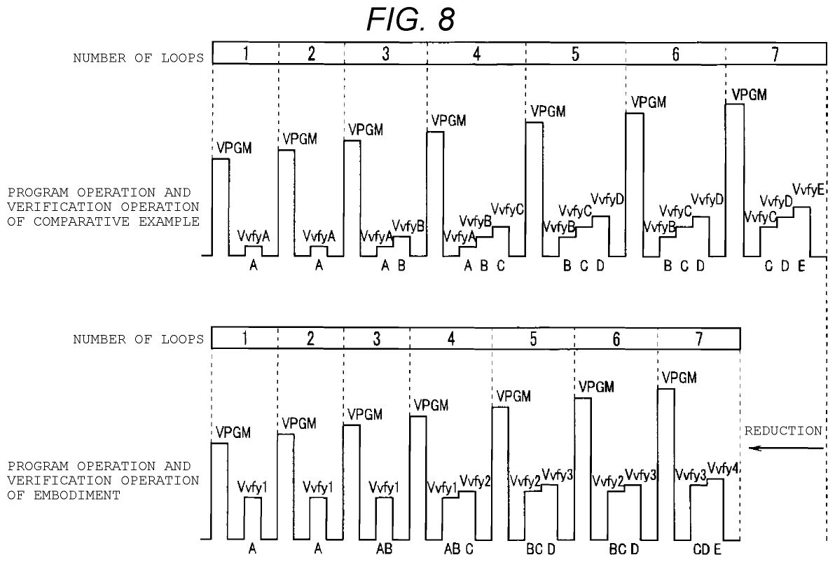

In addition, the verification operation of three or more states may not be performed once and may be divided into a plurality of times. FIG. 8 is an explanatory diagram illustrating another example of the change in the voltage applied to the selected word line WLsel in the program operation and the verification operation.

As illustrated in FIG. 8, in the fourth loop of the present embodiment, in a state in which the verification voltage Vvfy1 is applied to the selected word line WLsel, it is determined whether the memory cell transistors MT of Level A and Level B are in the write insufficient cell state or in the write complete cell state.

Next, in the state in which the verification voltage Vvfy2 for performing the verification for Level C is applied to the selected word line WLsel, it is determined whether the memory cell transistor MT of Level C is in the write insufficient cell state or in the write complete cell state.

In this manner, even when the verification operation in the three or more states is divided, for example, into the verification operation of twice, the number of times of verification can be reduced compared with that in the comparative example. Even in such a verification operation, the period of time for the write operation can be reduced compared with that in the comparative example, and thus the performance can be improved.

### Second Embodiment

Next, a second embodiment is described.

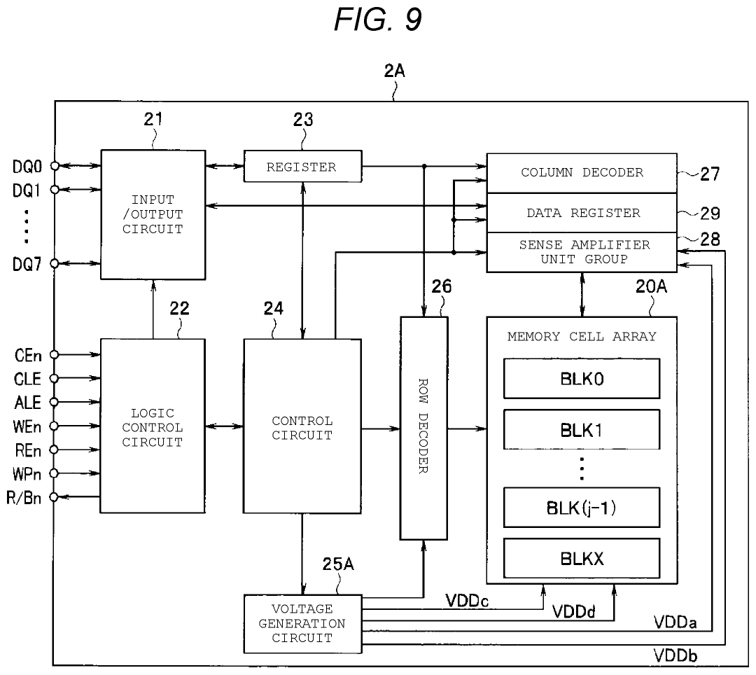

FIG. 9 is a block diagram illustrating an example of a nonvolatile memory 2A according to the second embodiment. In addition, in FIG. 9, the same configuration as in FIG. 2 is denoted by the same reference numeral, and the description thereof is omitted.

The nonvolatile memory 2A includes a memory cell array 20A and a voltage generation circuit 25A, instead of the memory cell array 20 and the voltage generation circuit 25 of the nonvolatile memory 2 of FIG. 2.

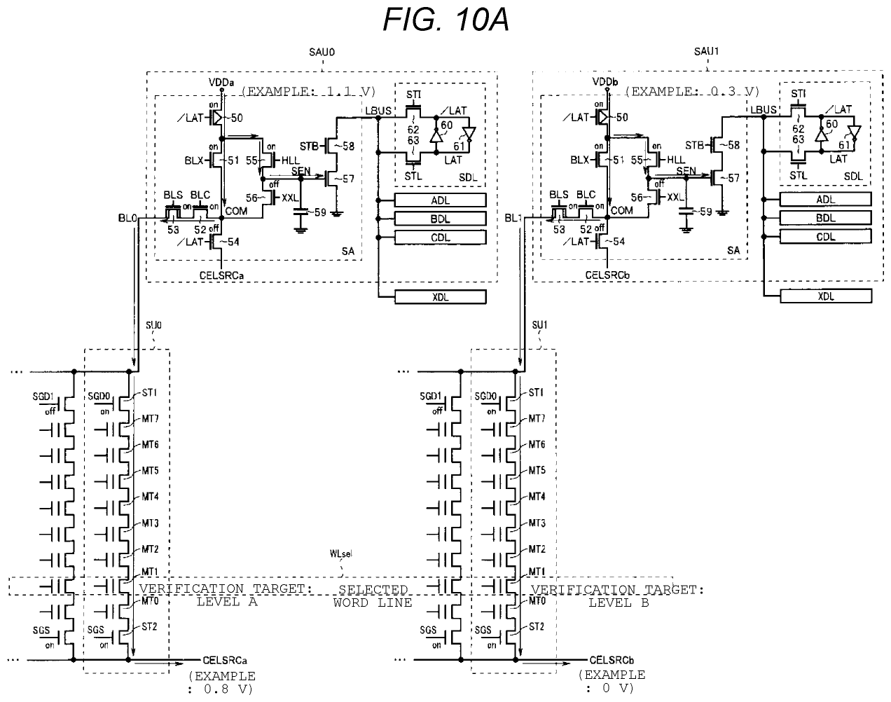

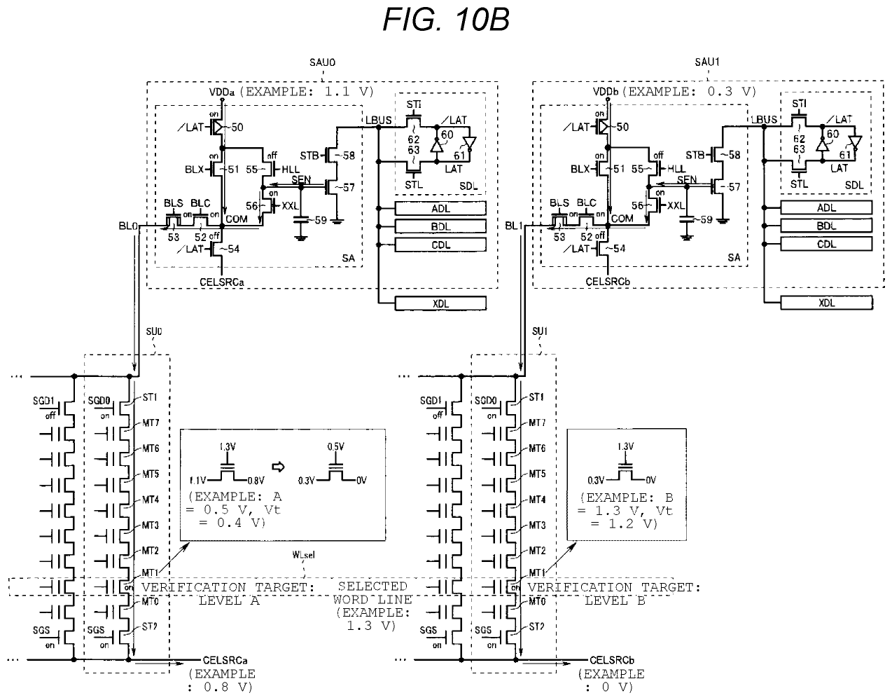

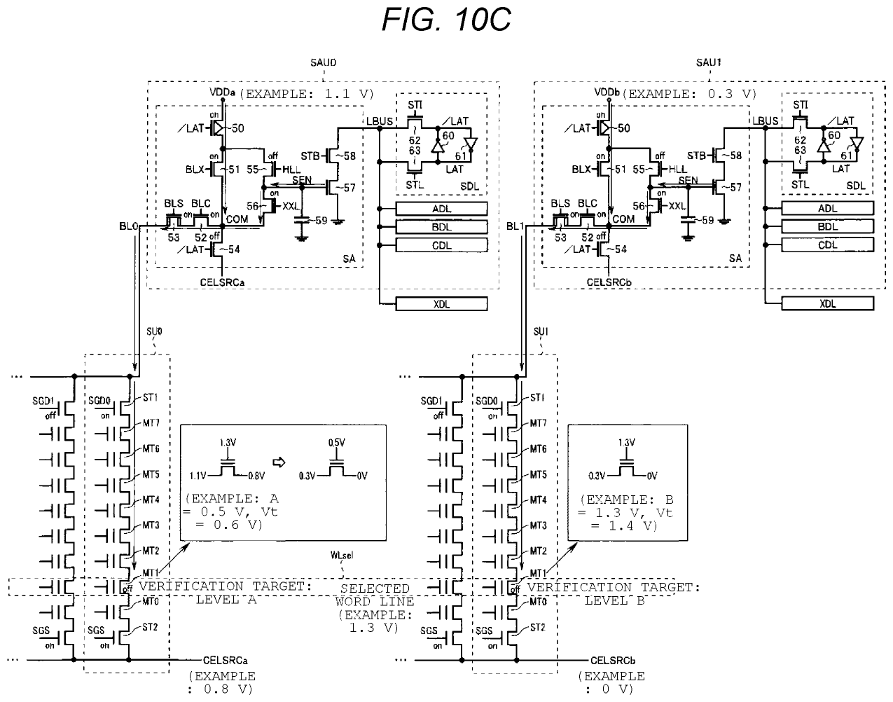

In the memory cell array 20 according to the first embodiment, the source line CELSRC is commonly connected to the plurality of bit lines BL. In contrast, in the memory cell array 20A according to the present embodiment, the source line CELSRC is divided for each of the bit lines BL. Specifically, as illustrated in FIG. 10 described below, a source line CELSRCa corresponding to the bit line BL0 is provided, and a source line CELSRCb corresponding to the bit line BL1 is provided.

The voltage generation circuit 25 applies different voltages VDDc and VDDd to the source lines CELSRCa and CELSRCb.

FIGS. 10A to 10C are explanatory diagrams illustrating an example of the verification operation of the second embodiment.

In the following description, the memory cell transistors MT1 of the selected string units SU0 and SU1 are set to the memory cell transistors MT to be verified. In the memory cell transistor MT1 of the selected string unit SU0, the target level of the verification operation is Level A. Meanwhile, in the memory cell transistor MT1 of the selected string unit SU1, the target level of the verification operation is Level B.

The control circuit 24 turns on the transistors 50, 51, 52, 53, and 55 of the sense amplifier units SAU0 and SAU1 and turns off the transistor 56.

The voltage generation circuit 25A applies the voltage VDDa (for example, 1.1 V) to the bit line BL0 connected to the memory cell transistor MT1 of which the target level of the verification operation is Level A. In addition, the voltage generation circuit 25A applies the voltage VDDc (for example, 0.8 V) to the source line CELSRCa connected to the memory cell transistor MT1 of which the target level of the verification operation is Level A.

Meanwhile, the voltage generation circuit 25A applies the voltage VDDb (for example, 0.3 V) to the bit line BL1 connected to the memory cell transistor MT1 of which the target level of the verification operation is Level B. In addition, the voltage generation circuit 25A applies the voltage VDDd (for example, 0 V) to the source line CELSRCb connected to the memory cell transistor MT1 of which the target level of the verification operation is Level B.

The row decoder 26 applies the predetermined voltage (for example, 2.5 V) to the select gate line SGD0 and the select gate line SGS and turns on the select gate transistors ST1 and ST2 of the selected string units SU0 and SU1.

Therefore, the sense node SEN of the selected string unit SU0 is charged to 1.1 V, and the sense node SEN of the selected string unit SU1 is charged to 0.3 V.

Next, as illustrated in FIG. 10B, the control circuit 24 turns off the transistor 55 and turns on the transistor 56 from the state of FIG. 10A.

Also, the row decoder 26 applies the verification voltage Vvfy1 (for example, 1.3 V) to the selected word line WLsel and applies the voltage VREAD (for example, 5 V) higher than the verification voltage Vvfy1 to an unselected word line.

In the memory cell transistor MT1 of the selected string unit SU0, a voltage of 1.3 V is applied to the gate terminal, a voltage of 1.1 V is applied to the source terminal, and a voltage of 0.8 V is applied to the drain terminal. This is equivalent to a case where a voltage of 0.5 V is applied to the gate terminal, a voltage of 0.3 V is applied to the source terminal, and a voltage of 0 V is applied to the drain terminal.

Therefore, since a case where the threshold voltage Vt is 0.4 V is equivalent to a case where the verification voltage Vvfy1 of 0.5 V is input to the gate terminal, the memory cell transistor MT1 of the selected string unit SU0 is turned on. Therefore, the current flows from the sense node SEN to the source line CELSRCa via the transistors 56, 52, and 53, and thus the voltage of the sense node SEN decreases.

In addition, since the verification voltage Vvfy1 of 1.3 V is input to the gate terminal, while the threshold voltage Vt is 1.2 V, the memory cell transistor MT1 of the selected string unit SU1 is turned on. Therefore, in the sense node SEN of the sense amplifier unit SAU1, the current flows from the sense node SEN to the source line CELSRCb via the transistors 56, 52, and 53 and the voltage of the sense node SEN decreases.

When the sense node SEN is discharged, the control circuit 24 determines that the verification is failed. For the memory cell transistor MT determined that the verification is failed, the control circuit 24 increases a voltage VPGM applied to the selected word line WLsel to be higher than that in a case where the previous program operation since the writing is not completed and performs a program operation.

FIG. 10C illustrates an example in which the threshold voltage Vt of the memory cell transistor MT1 of the selected string unit SU0 is increased to 0.6 V, and the threshold voltage Vt of the memory cell transistor MT1 of the selected string unit SU1 is increased to 1.4 V by the program operation. The operation state (on/off of the transistor or the applied voltage) in the verification operation after the program operation is the same as the state in FIG. 10B.

The memory cell transistor MT1 of the selected string unit SU0 is turned off, since a case where the threshold voltage Vt is 0.6 V is equivalent to a case where the verification voltage Vvfy1 of 0.5 V is input to the gate terminal. Therefore, the current does not flow from the sense node SEN to the source line CELSRCa, the sense node SEN of the sense amplifier unit SAU0 is not discharged.

In addition, the memory cell transistor MT1 of the selected string unit SU1 is turned off since the verification voltage Vvfy1 of 1.3 V is input to the gate terminal while the threshold voltage Vt is 1.4 V. Accordingly, the current does not flow from the sense node SEN to the source line CELSRCb, the sense node SEN of the sense amplifier unit SAU1 is not discharged.

When the sense node SEN is not discharged, the control circuit 24 determines that the verification is passed. The control circuit 24 determines that the write operation for the memory cell transistor MT of which the verification is passed is completed and does not perform the following program operations and verification operations.

In the above, according to the present embodiment, the source line CELSRC is divided for each of the bit lines BL, and specifically, the source line CELSRC is divided into the source lines CELSRCa and CELSRCb corresponding to the bit lines BL0 and BL1. Also, according to the target level of the verification operation, by applying the different voltages VDDc and VDDd to the source lines CELSRCa and CELSRCb, the back gate bias is changed, and the plurality of threshold values are read with one verification voltage Vvfy1.

As a result, similarly to the first embodiment, the semiconductor memory device according to the present embodiment can reduce the number of times of verification, and the performance can be improved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a first bit line connected to one end of a first string including a first select transistor, a plurality of memory cell transistors, and a second select transistor;
a second bit line connected to one end of a second string including a third select transistor, a plurality of memory cell transistors, and a fourth select transistor;
a source line commonly connected to the other end of the first string and the other end of the second string;
a word line commonly connected to respective gates of the memory cell transistors in one or more same rows of the first string and the second string;
a voltage generation circuit configured to apply a first voltage to the first bit line according to a first target level during a verification operation, apply a second voltage to the second bit line according to a second target level, and apply a third voltage to the source line; and
a row decoder configured to apply a fourth voltage to the word line to which a first one of the memory cell transistors of the first string and a second one of the memory cell transistors of the second string to be verified are connected during the verification operation.

2. The semiconductor memory device according to claim 1, further comprising:
a first sense amplifier connected to the first bit line and including a first sense node;
a second sense amplifier connected to the second bit line and including a second sense node; and
a control circuit configured to determine whether verification of the first memory cell transistor of the first string is passed based on whether the first sense node is charged and determine whether verification of the second memory cell transistor of the second string is passed based on whether the second sense node is charged.

3. The semiconductor memory device according to claim 2,
wherein the control circuit is configured to determine that verification of the first memory cell transistor of the first string is failed when the first sense node is charged, and determine that verification of the first memory cell transistor of the first string is passed when the first sense node is not charged.

4. The semiconductor memory device according to claim 2,
wherein the control circuit is configured to determine that verification of the second memory cell transistor of the second string is failed when the second sense node is charged, and determine that verification of the second memory cell transistor of the second string is passed when the second sense node is not charged.

5. A method for verifying memory cell transistors, comprising:
connecting a first bit line to one end of a first string including a first select transistor, a plurality of memory cell transistors, and a second select transistor;
connecting a second bit line to one end of a second string including a third select transistor, a plurality of memory cell transistors, and a fourth select transistor;
connecting a source line to the other end of the first string and the other end of the second string;
connecting a word line to respective gates of the memory cell transistors in one or more same rows of the first string and the second string;
applying a first voltage to the first bit line according to a first target level during a verification operation, applying a second voltage to the second bit line according to a second target level, and applying a third voltage to the source line; and
applying a fourth voltage to the word line to which a first one and a second one of the memory cell transistors to be verified are connected during the verification operation.

6. The method of claim 5, further comprising:
determining whether verification of the first memory cell transistor of the first string is passed based on whether a first sense node of a first sense amplifier connected to the first bit line is charged; and
determining whether verification of the second memory cell transistor of the second string is passed based on whether a second sense node of a second sense amplifier connected to the second bit line is charged.

7. The method of claim 6, further comprising:
determining that verification of the first memory cell transistor of the first string is failed when the first sense node is charged; and
determining that verification of the first memory cell transistor of the first string is passed when the first sense node is not charged.

8. The method of claim 6, further comprising:
determining that verification of the second memory cell transistor of the second string is failed when the second sense node is charged; and
determining that verification of the second memory cell transistor of the second string is passed when the second sense node is not charged.

9. The semiconductor memory device according to claim 1, further comprising:
a first transistor provided between the voltage generation circuit and the first bit line, and
a second transistor provided between the voltage generation circuit and the second bit line,
wherein after applying the first voltage and the second voltage, the first transistor and the second transistor are turned off.

10. The semiconductor memory device according to claim 1, wherein after applying the first voltage and the second voltage, the second select transistor and the fourth select transistor are turned on.

11. The semiconductor memory device according to claim 1, wherein after applying the first voltage and the second voltage, the third voltage is applied.

12. The method according to claim 5, further comprising:
after applying the first voltage and the second voltage, turning off a first transistor and a second transistor,
wherein the first transistor is provided between a voltage generation circuit and the first bit line, and the second transistor is provided between the voltage generation circuit and the second bit line.

13. The method according to claim 5, further comprising:
after applying the first voltage and the second voltage, turning on the second select transistor and the fourth select transistor.

14. The method according to claim 5, further comprising:
after applying the first voltage and the second voltage, applying the third voltage.
